(19) United States
(12) Patent Application Publication
(10) Pub. No.: US 2007/0023203 A1
(43) Pub. Date: Feb. 1, 2007

(54) Method and system for customized radio frequency shielding using solder bumps

(76) Inventors: Gustavo D. Leizerovich, Aventura, FL (US); Vahid Goudarzi, Coral Springs, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(21) Appl. No.: 11/189,250

(22) Filed: Jul. 26, 2005

(51) Int. Cl. H05K 9/00

(52) U.S. Cl. 174/255; 361/818; 174/262; 361/803

(57) ABSTRACT

An RF shield arrangement (30) includes a first substrate (12) having a first or top ground plane (41), a second substrate (22) having a second or bottom ground plane (42), and a plurality of solder bumped areas (14) coupled between the top ground plane and the bottom ground plane forming at least one radio frequency shielded compartment. The top and bottom ground planes can be placed on or within the respective substrate so long as they serve to form the RF shielding in accordance with the embodiments herein.

### FIELD OF THE INVENTION

This invention relates generally to shielding, and more particularly to a method and system for providing a customizable shield using solder balls or bumps.

### BACKGROUND OF THE INVENTION

The current approach to shielding multiple cavities in subscriber radios uses individual shields for each section. Even though this is a valid approach in terms of shielding effectiveness, such approach unnecessarily uses added printed circuit board (PCB) space since adjacent sections or cavities or shields end up taking two or more shield tracks.

Another approach used in radio frequency (RF) modules is to use a single shield with multiple cavities or compartments. To accommodate for co-planarities a large amount of solder paste is dispensed via overprinting. However this method requires clearance around the shield track to allow for over printing and as a result the module size is increased.

Another approach is to dispense conductive epoxy to provide electrical connection between the shield and the track on the PCB. There are reliability issues with this method due to poor adhesion. Yet another method utilizes cladding by dispensing a smaller amount of solder paste, reflowing the paste, applying a thin film of flux to the shield, placing the fluxed shield on top of the cladded track and reflowing the cladded track and shield together. This methodology demands a series of extra steps and has limitations on the shape of the cavities that can be shielded. Additionally, the cladding technique requires keep out areas in the corners to accommodate the metal shield radius. None of the techniques discussed above enable shielding of multiple sections of a radio PCB or RF module with the ability to customize the shape of the shield in a space efficient manner.

### SUMMARY OF THE INVENTION

Embodiments in accordance with the present invention can provide a method and system for customizing a radio frequency shield with one or more compartments or cavities in a space efficient manner.

In a first embodiment of the present invention, a radio frequency (RF) shield arrangement can include a first substrate having a top ground plane, a second substrate having a bottom ground plane, and a plurality of solder bumped areas coupled between the top ground plane and the bottom ground plane forming at least one radio frequency shielded compartment. The radio frequency shield arrangement can include at least one component within the RF shielded compartment. The plurality of solder bumped areas can form a wall for the one or more RF shielded compartments. The first substrate can include a plated through hole or a conductive via electrically coupled to the top ground plane while the second substrate includes a plated through-hole or a conductive via electrically coupled to the bottom ground plane. The second substrate can further include a plurality of ground pads on a surface of the second substrate for mating with the a plurality of solder bumped areas. Thus, the plurality of solder bumped areas coupled between the top ground plane and the bottom ground plane can form a multi-compartment RF shield. Note, the plurality of solder bumped areas can be a plurality of polymer-filled solder bumps. In a further alternative of the first arrangement, the RF shield arrangement can further include at least one package on package (PoP) stacked integrated circuit (IC) stacked between the first substrate and the second substrate such that a plurality of solder bumps and conductive vias within the at least one package on package forms a ground shield wall.

In a second embodiment of the present invention, a multi-compartment radio frequency shield arrangement can include a first substrate having a first ground plane, a second substrate having a second ground plane, and a plurality of solder bumped areas coupled between the first ground plane and the second ground plane forming a plurality of radio frequency shielded compartments. The RF shield arrangement can further include at least one component within each compartment among the plurality of RF shielded compartments. The plurality of solder bumped areas can form a wall for the plurality of radio frequency shielded compartments. The second substrate can further include a plurality of ground pads on a surface of the second substrate for mating with the a plurality of solder bumped areas. The multi-compartment RF shield arrangement can further include at least one package on package stacked integrated circuit stacked between the first substrate and the second substrate such that a plurality of solder bumps and conductive vias within the at least one package on package forms a ground shield wall. Note, although in one embodiment the first ground plane can be a top ground plane and the second ground plane can be a bottom ground plane, embodiments herein certainly contemplate ground planes that lie either on top surfaces, bottom surfaces, as well as embedded within surfaces of respective substrates.

In a third embodiment of the present invention, a method of forming a customized RF shielded compartment or compartments can include the steps of solder bumping a first substrate with a plurality of solder bumps in a pattern matching a shield track, placing at least one component on a second substrate, and applying the first substrate to the second substrate such that the plurality of solder bumps mate with the plurality of ground pads in a pattern matching a shield track. Note, the first substrate has a first ground plane coupled to the plurality of solder bumps and the second substrate has a plurality of ground pads in the pattern matching the shield track and coupled to a second ground plane. Further note, the pattern matching the shield track can form a multi-compartment radio frequency shield and the plurality of solder bumps form a wall for the customized radio frequency shielded compartment or compartments. The method can further include the step of reflowing the plurality of solder bumps to form the customized shielded compartment or compartments. The plurality of solder bumps can electrically couple to the first ground plane by a plated through hole or a conductive via in the first substrate coupled to the first ground plane and the plurality of solder bumps can electrically couple to the second ground plane by a plated through-hole or a conductive via in the second substrate coupled to the second ground plane. Although conventional solder bumps or balls can be used, polymer-filled or resin-filled solder bumps or balls can also be used for the plurality of solder bumps.

Other embodiments, when configured in accordance with the inventive arrangements disclosed herein, can include a system for performing and a machine readable storage for causing a machine to perform the various processes and methods disclosed herein.

### BRIEF DESCRIPTION OF THE DRAWINGS

FIG. 1 is a top view of a bottom side of a first or top substrate having a plurality of solder bumps in accordance with an embodiment of the present invention.

FIG. 2 is a top view of a second or bottom substrate having a plurality of solder pads in accordance with an embodiment of the present invention.

FIG. 3 is a side view of a RF shield arrangement in accordance with an embodiment of the present invention.

FIG. 4 is an expanded view of a portion of the side view of FIG. 3 illustrating the use of the plurality of solder bumps to form the RF shield arrangement.

FIG. 5 is a side view of a package on package stacked integrated circuit using the plurality of solder bumps and ground planes to form a shielded cavity in accordance with an embodiment of the present invention.

FIG. 6 is a flow chart illustrating a method of forming a customized RF shielded compartment or compartments in accordance with an embodiment of the present invention.

### DETAILED DESCRIPTION OF THE DRAWINGS

While the specification concludes with claims defining the features of embodiments of the invention that are regarded as novel, it is believed that the invention will be better understood from a consideration of the following description in conjunction with the figures, in which like reference numerals are carried forward.

Embodiments in accordance with present invention enable the formation of a shield by using a substrate having a metalized surface such as a printed circuit board (PCB) having the top ground plane and solder bumps or balls to create the walls. The shield can be created with similar technology as currently used for ball grid array (BGA) packages. There are no limitations in the type or form of shape of the cavities or compartments, as well as the number of cavities or compartments. The distance between balls can be selected so that the gap between the balls is a very small fraction of the wavelength involved to maintain the electromagnetic shielding integrity. The spacing used in current BGA packages can serve more than adequately for shielding purposes for operating frequencies up to 5 GigaHertz and possibly higher.

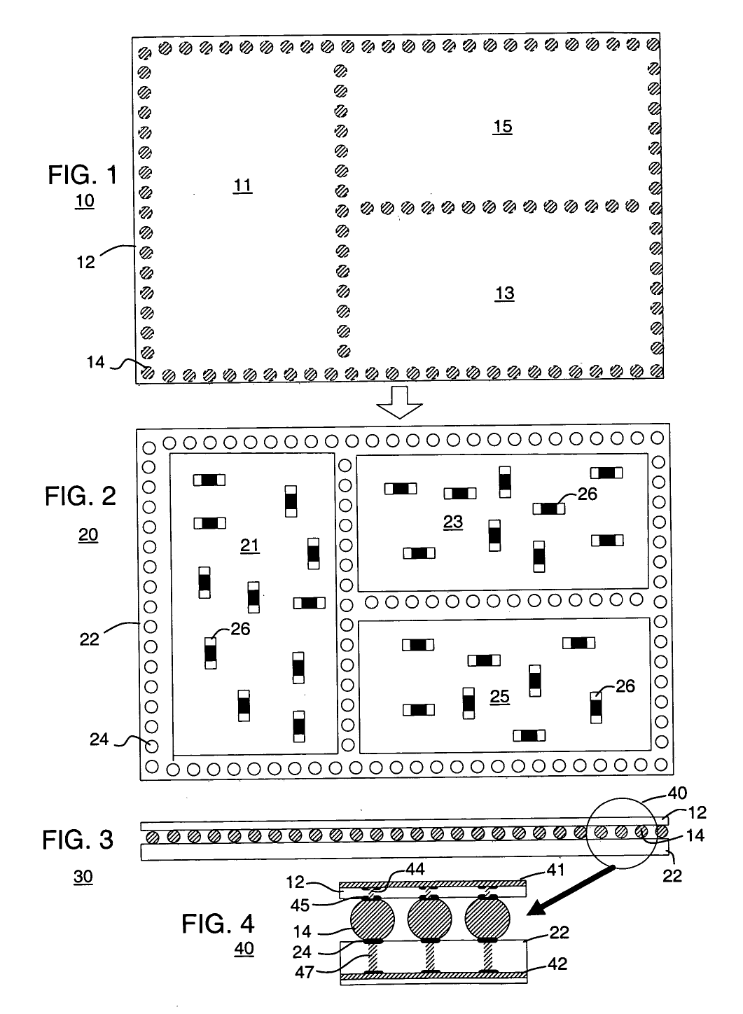

Referring to FIGS. 1-4, an RF shielded arrangement 30 is illustrated having a first or top substrate 12 having a plurality of solder bumps or balls 14 formed in a shield track pattern. The substrate 12 along with the solder bumps 14 form a solder bumped substrate 10 that can be placed on top of a second or bottom substrate 22 having a plurality of solder pads 24 formed in the shield track pattern to mate with the plurality of solder bumps 14 when the first substrate 12 and second substrate 22 are sandwiched together as illustrated in FIG. 3. In this particular embodiment, the shield track pattern will form three separate cavities or compartments between areas 11 and 21, areas 13 and 23, and areas 15 and 25 among the first and second substrates respectively. Besides the plurality of solder pads 24, second or bottom substrate 22 can further include at least one component 26 or a plurality of components 26 placed within each of the areas 21, 23, and 25 of the substrate 22 for form a populated printed circuit board 20.

Referring to the magnified area 40 in FIG. 3 and the expanded or magnified view in FIG. 4 the RF shield arrangement 30 more particularly includes the first substrate 12 having a first or top ground plane 41, a second substrate 22 having a second or bottom ground plane 42, and a plurality of solder bumped areas 14 coupled between the top ground plane 41 and the bottom ground plane 42 forming at least one radio frequency shielded compartment. Note, the ground planes shown in FIG. 4 are for illustration purposes and do not necessarily need to be placed on a top surface or a bottom surface of a substrate or even need to be embedded within a substrate. The top and bottom ground planes can be placed on or within the respective substrate so long as they serve to form the RF shielding in accordance with the embodiments herein.

The radio frequency shield arrangement can further include at least one component 26 (see FIG. 2) within the RF shielded compartment. The plurality of solder bumped areas 14 can form a wall for the one or more RF shielded compartments. The first substrate 12 can include a plated through hole or a conductive via 44 electrically coupled to the top ground plane 41 while the second substrate 22 can include a plated through-hole or a conductive via 47 electrically coupled to the bottom ground plane 42. The second substrate 22 can further include a plurality of ground pads 24 on a surface of the second substrate 22 for mating with the a plurality of solder bumped areas 14. The first substrate 12 can also include a plurality of ground pads 45. Thus, the plurality of solder bumped areas 14 coupled between the top ground plane 41 and the bottom ground plane 42 can form a multi-compartment RF shield or arrangement 30. Note, the plurality of solder bumped areas 14 can be a plurality of polymer-filled solder bumps such as resin-filled solder made by Sekisui Chemical Co., Ltd of Japan. Such resin-filled or polymer-filled solder can provide added height to a shield if needed even after reflow.

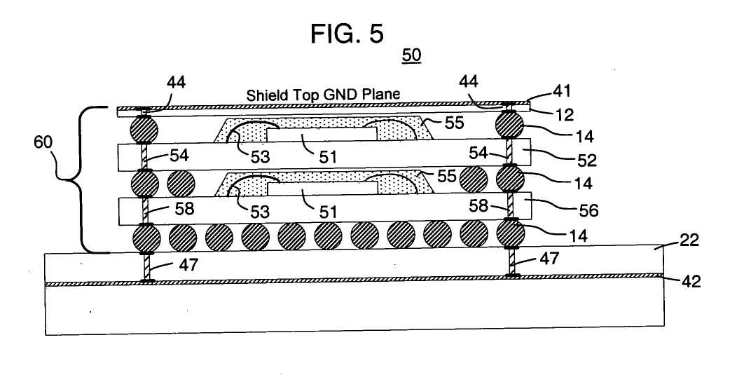

In a further alternative of the first arrangement, a RF shield arrangement 50 as illustrated in FIG. 5 can further include at least one package on package (PoP) stacked integrated circuit (IC) stacked between the first substrate 12 and the second substrate 22 such that a plurality of solder bumps 14 and conductive vias (54 and 58) within the at least one package on package forms a ground shield wall.

More specifically, the PoP RF shield arrangement 50 can include the top substrate 12 and bottom substrate 22 with their respective ground planes 41 and 42 and at least one stacked package-on-package which can include a first package substrate 52 having a component such as an integrated circuit (IC) die 51 wirebonded with wires 53 to circuitry on the substrate 52. Note, “flip chip” technology or other suitable techniques can be used alternatively instead of wirebonding in order to attach IC 51 to the substrates 52 and 56. The IC die 51 and wirebond wires 53 can be overmolded with glob-top, resin or other insulative material 55. Likewise, a second package substrate 56 stacked below the first package substrate 52 also includes an integrated circuit (IC) die 51 wirebonded with wires 53 to circuitry on the substrate 56 all overmolded with glob-top, resin or other insulative material 55. The arrangement 50 forms a RF shielded cavity using the top ground plane 41, the bottom ground plane 42, and shield ground walls 60 formed from solder bumps or balls 14, conductive vias or through-holes 44, 54, 58, and 47. Thus, RF shield arrangements in accordance with the present invention can use a laminate substrate for a top plane and balls or solder columns to create the side walls to not only provide multi-cavity shielding by forming multiple shielded cavities of arbitrary shapes, but also to shield stacked packages of varying heights based on the number of stacked packages. Note, although not shown, substrates 52 and 56 can also include ground planes connected to vias 54 and 56 in order to provide shielding between the different ICs (51) on the respective substrates 52 and 56.

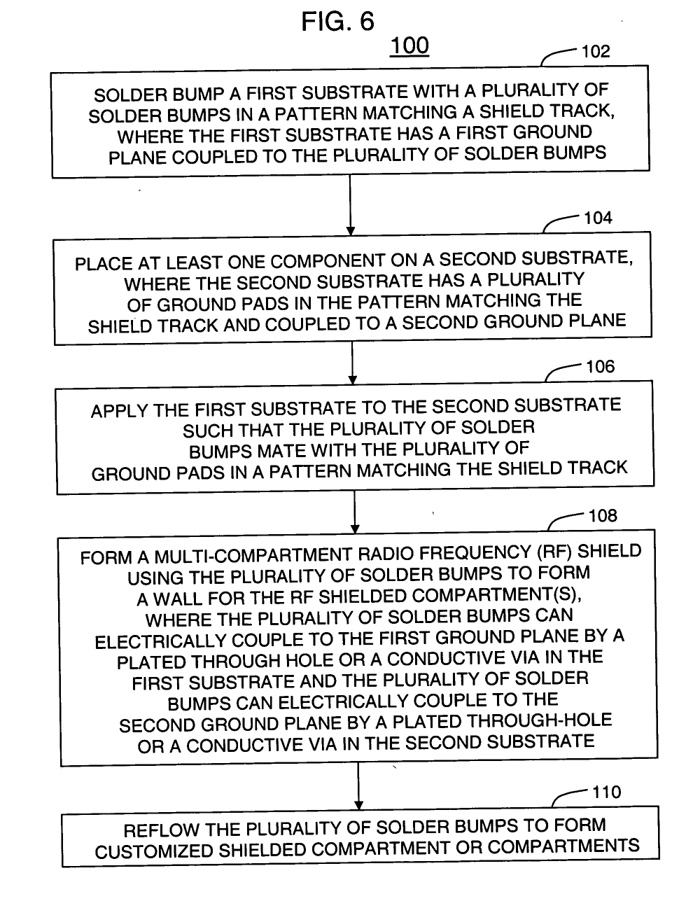

Referring to FIG. 6, a flow chart illustrating a method 100 of forming a customized RF shielded compartment or compartments can include the step 102 of solder bumping a first substrate with a plurality of solder bumps in a pattern matching (which can include substantially matching) a shield track, placing at least one component on a second substrate at step 104, and applying the first substrate to the second substrate such that the plurality of solder bumps mate with the plurality of ground pads in a pattern matching a shield track at step 106. Note, the first substrate has a first ground plane coupled to the plurality of solder bumps and the second substrate has a plurality of ground pads in the pattern matching the shield track and coupled to a second ground plane. Further note at step 108, the pattern matching the shield track can form a multi-compartment radio frequency shield and the plurality of solder bumps form a wall for the customized radio frequency shielded compartment or compartments. The method 100 can further include the step 110 of reflowing the plurality of solder bumps to form the customized shielded compartment or compartments. The plurality of solder bumps can electrically couple to the first ground plane by a plated through hole or a conductive via in the first substrate coupled to the first ground plane and the plurality of solder bumps can electrically couple to the second ground plane by a plated through-hole or a conductive via in the second substrate coupled to the second ground plane.

In light of the foregoing description, it should also be recognized that embodiments in accordance with the present invention can be realized in numerous configurations contemplated to be within the scope and spirit of the claims. For example, although the embodiments shown illustrate a solder bumped top substrate placed on a bottom substrate having matching solder pads, other embodiments within contemplation of the scope of the claims can also include a solder bumped bottom substrate that mates with a top substrate having corresponding solder pads. Additionally, the description above is intended by way of example only and is not intended to limit the present invention in any way, except as set forth in the following claims.

What is claimed is:

1. A radio frequency shield arrangement, comprising:
a first substrate having a top ground plane;
a second substrate having a bottom ground plane; and
a plurality of solder bumped areas coupled between the top ground plane and the bottom ground plane forming at least one radio frequency shielded compartment.

2. The radio frequency shield arrangement of claim 1, wherein the plurality of solder bumped areas form a wall for the at least one radio frequency shielded compartment.

3. The radio frequency shield arrangement of claim 1, wherein the first substrate further comprises a plated through hole or a conductive via electrically coupled to the top ground plane.

4. The radio frequency shield arrangement of claim 1, wherein the second substrate further comprises a plated through-hole or a conductive via electrically coupled to the bottom ground plane.

5. The radio frequency shield arrangement of claim 1, wherein the second substrate further comprises a plurality of ground pads on a surface of the second substrate for mating with the plurality of solder bumped areas.

6. The radio frequency shield arrangement of claim 1, wherein the radio frequency shield arrangement further comprises at least one component within the at least one radio frequency shielded compartment.

7. The radio frequency shield arrangement of claim 1, wherein the plurality of solder bumped areas comprises a plurality of polymer-filled solder bumps.

8. The radio frequency shield arrangement of claim 1, wherein the plurality of solder bumped areas coupled between the top ground plane and the bottom ground plane form a multi-compartment radio frequency shield.

9. The radio frequency shield arrangement of claim 1, wherein the radio frequency shield arrangement further comprises at least one package on package stacked integrated circuit stacked between the first substrate and the second substrate such that a plurality of solder bumps and conductive vias within the at least one package on package form a ground shield wall.

10. A multi-compartment radio frequency shield arrangement, comprising:
a first substrate having a first ground plane;
a second substrate having a second ground plane; and
a plurality of solder bumped areas coupled between the first ground plane and the second ground plane forming a plurality of radio frequency shielded compartments.

11. The multi-compartment radio frequency shield arrangement of claim 10, wherein the plurality of solder bumped areas form a wall for the plurality of radio frequency shielded compartments.

12. The multi-compartment radio frequency shield arrangement of claim 10, wherein the second substrate further comprises a plurality of ground pads on a surface of the second substrate for mating with the plurality of solder bumped areas.

13. The multi-compartment radio frequency shield arrangement of claim 10, wherein the radio frequency shield arrangement further comprises at least one component within each compartment among the plurality of radio frequency shielded compartments.

14. The multi-compartment radio frequency shield arrangement of claim 10, wherein the multi-compartment radio frequency shield arrangement further comprises at least one package on package stacked integrated circuit stacked between the first substrate and the second substrate such that a plurality of solder bumps and conductive vias within the at least one package on package form a ground shield wall.

15. A method of forming a customized radio frequency shielded compartment or compartments, comprising the steps of:
solder bumping a first substrate with a plurality of solder bumps in a pattern matching a shield track, wherein the first substrate has a first ground plane coupled to the plurality of solder bumps;
placing at least one component on a second substrate, wherein the second substrate has a plurality of ground pads in the pattern matching the shield track and coupled to a second ground plane; and
applying the first substrate to the second substrate such that the plurality of solder bumps mate with the plurality of ground pads in the pattern matching the shield track.

16. The method of claim 15, wherein the method further comprises the step of reflowing the plurality of solder bumps to form the customized shielded compartment or compartments.

17. The method of claim 15, wherein the plurality of solder bumps form a wall for the customized radio frequency shielded compartment or compartments.

18. The method of claim 15, wherein the plurality of solder bumps electrically couples to the first ground plane by a plated through hole or a conductive via in the first substrate coupled to the first ground plane and the plurality of solder bumps electrically couples to the second ground plane by a plated through-hole or a conductive via in the second substrate coupled to the second ground plane.

19. The method of claim 15, wherein the step of solder bumping the first substrate with the plurality of solder bumps comprises solder bumping with a plurality of polymer-filled solder bumps.

20. The method of claim 15, wherein the pattern matching the shield track forms a multi-compartment radio frequency shield.
